(19) United States
(12) Patent Application Publication
(10) Pub. No.: US 2023/0202079 A1
(43) Pub. Date: Jun. 29, 2023

(54) RESIN MOLDING APPARATUS, COVER PLATE, AND RESIN MOLDED ARTICLE PRODUCTION METHOD

(71) Applicant: TOWA CORPORATION, Kyoto-shi, Kyoto (JP)

(72) Inventors: Yoshihisa KAWAMOTO, Uji-shi, Kyoto (JP); Noriyuki TAKAHASHI, Otsu-shi, Shiga (JP); Keita MIZUMA, Kyoto-shi, Kyoto (JP)

(73) Assignee: TOWA CORPORATION, Kyoto-shi, Kyoto (JP)

(21) Appl. No.: 17/927,039

(22) PCT Filed: Apr. 28, 2021
(86) PCT No.: PCT/JP2021/016946

§ 371 Date: Nov. 22, 2022

(30) Foreign Application Priority Data
May 25, 2020 (JP) 2020-090415

(51) Int. Cl. B29C 43/36; B29C 43/18

(52) U.S. Cl. CPC B29C 43/36; B29C 43/18; B29C 2043/3605; B29L 2031/34

(57) ABSTRACT

The present invention is intended to prevent resin from sticking to a molding surface of a first molding die that holds an object to be molded, without using a release film, and is a resin molding apparatus that performs resin molding on the object to be molded, the resin molding apparatus including: a first molding die that holds the object to be molded; a second molding die that is provided in a manner facing the first molding die and that has a cavity for holding resin material; and a cover plate that is provided between the object to be molded and the first molding die, that covers a molding surface of the first molding die, and that has rigidity for maintaining its own shape.

### TECHNICAL FIELD

The present invention relates to a resin molding apparatus, a cover plate, and a method for producing a resin molded product.

### BACKGROUND ART

As a resin molding apparatus that molds resin using a resin material, there is a resin molding apparatus that includes an upper molding die holding an object to be molded such as a substrate, a lower molding die provided in a manner facing the upper molding die and having a cavity for holding the resin material, and that seals the object to be molded with the resin by clamping the upper molding die with the lower molding die.

In such a resin molding apparatus, when the molding dies are clamped, the resin may overrun from the periphery of the object to be molded and creep onto the back surface of the object to be molded, for example, and stick to a molding surface of the upper molding die. If the subsequent resin molding is performed using the upper molding die having the resin stuck thereto, a product defect such as cracking of the object to be molded may occur. In particular, thin substrates often result in such product defects.

In order to solve this problem, in the resin molding apparatus disclosed in Patent Literature 1 or Patent Literature 2, a release film is placed on an upper molding die that holds a substrate, between the upper molding die and the substrate, so as to prevent the resin from sticking to the molding surface of the upper molding die.

### CITATION LIST

### Patent Literature

Patent Literature 1: JP 2013-162041 A
Patent Literature 2: JP 2019-125661 A

### SUMMARY OF INVENTION

### Technical Problem

However, because release films are expensive, running costs become increased. In addition, because the release film is usually discarded every time the resin molding is carried out, the disposal cost also becomes increased. In particular, when the size of the object to be molded is large (for example, φ 300 mm or greater), the release film also needs to have a larger size to cover the molding surface of the upper molding die (molding die), and thus, the cost also becomes increased. Furthermore, because the release film is soft and needs to be conveyed onto the upper molding die while maintaining the desired shape, the structure of the conveying mechanism for conveying the release film becomes complicated. In addition, because the release film needs to be affixed to the molding surface of the upper molding die without any wrinkles, the structure of the molding dies for it also becomes complicated.

Hence, the present invention has been made to solve the problems described above, and a main object of the present invention is to prevent a resin from sticking to a molding surface of a first molding die for holding an object to be molded, without using a release film.

### Solution to Problem

In other words, a resin molding apparatus according to the present invention is a resin molding apparatus that molds resin on an object to be molded, the resin molding apparatus including: a first molding die that holds the object to be molded; a second molding die that is provided in a manner facing the first molding die and that has a cavity for holding resin material; and a cover plate that is provided between the object to be molded and the first molding die, that covers a molding surface of the first molding die, and that has rigidity for maintaining a shape of the cover plate. Advantageous Effects of Invention

According to the present invention having a configuration described above, it is possible to prevent the resin from sticking to the molding surface of the first molding die that holds the object to be molded, without using a release film.

### BRIEF DESCRIPTION OF DRAWINGS

FIG. 1 is a plan view schematically illustrating a configuration of a resin molding apparatus according to a present embodiment.

FIG. 2 is a cross-sectional view schematically illustrating a configuration of a resin-molding module according to the embodiment.

FIG. 3 is a cross-sectional view schematically illustrating structures around an upper molding die according to the embodiment.

FIG. 4 is a schematic view of the upper mold suctioning to hold a cover plate and a substrate, viewed from below.

FIG. 5 is a schematic illustrating (a) before attaching a cover plate, and (b) after attaching the cover plate, in a method for producing a resin molded product according to the embodiment.

FIG. 6 is a schematic illustrating (c) after holding a substrate to the upper molding die by suctioning, and (d) after supplying resin material, in the method for producing a resin molded product according to the embodiment.

FIG. 7 is a schematic illustrating (e) during resin-molding and (f) after the resin-molding, in the method for producing a resin molded product according to the embodiment.

FIG. 8 is a schematic illustrating (g) the molded substrate being taken out, and (h) the cover plate being taken out, in the method for producing a resin molded product according to the embodiment.

Reference Signs List

| | |
|---|---|
| 100 | resin molding apparatus |
| J | resin material |
| W | object to be molded |
| P | resin molded product |
| 2 | upper molding die (first molding die) |
| 2P | molding surface |
| 2 h | suction port |
| 3 | lower molding die (second molding die) |
| 3C | cavity |
| 4 | molding die clamping mechanism |
| 6 | cover plate |
| 6 h | through hole |
| 7 | holding mechanism |
| 8 | cover plate storage |
| 9 | cover plate conveying mechanism |

### DESCRIPTION OF EMBODIMENTS

The present invention will be explained more in detail using some examples. However, the following explanations are not intended to limit the scope of the present invention in any way.

As described above, a resin molding apparatus according to the present invention is a resin molding apparatus that molds resin on an object to be molded, the resin molding apparatus including: a first molding die that holds the object to be molded; a second molding die that is provided in a manner facing the first molding die and that has a cavity for holding resin material; and a cover plate that is provided between the object to be molded and the first molding die, that covers a molding surface of the first molding die, and that has rigidity for maintaining a shape of the cover plate.

In this resin molding apparatus, because the molding surface of the first molding die that holds the object to be molded is covered by the cover plate, it is possible to prevent the resin from sticking to the molding surface of the first molding die, without using a release film. Therefore, it is possible to reduce the running cost and the disposal cost accrued by the use of a release film. Even if there is some substance such as resin sticking on the molding surface of the first molding die, or a foreign substance sticking on the back surface of the object to be molded, because the sticking substance is covered under the cover plate, product defects such as cracking of the object to be molded can be prevented. By covering the molding surface of the first molding die with the cover plate in the manner described above, the safety of the product can be ensured, and the resin molding apparatus can be operated for a long period of time.

In addition, because the cover plate has rigidity for maintaining its own shape, a mechanism for conveying the cover plate can be simplified. For example, it is possible to convey the cover plate using a conveying mechanism having the same structure as that for conveying the object to be molded.

Furthermore, because the cover plate has rigidity for maintaining its own shape and is not soft as the release film, the cover plate rarely becomes wrinkled after being attached to molding surface of the first molding die, so that the structure of the molding die does not become complicated, too, compared with when a release film is used.

Specifically, it is preferable for the cover plate to be made of a member having rigidity for maintaining the shape of the cover plate against a weight of the cover plate. In other words, the cover plate is made of a member having rigidity for maintaining its own shape when there is no external force other than the gravity applied thereto.

The cover plate is preferably made of metal, resin, or paper.

In particular, with a cover plate made of metal or resin, it becomes easy to clean and to reuse the cover plate, so that the running cost can be reduced, compared with when a release film is used.

In addition, in particular, with a cover plate made of resin or paper, the cover plate may be formed at a lower cost, and can also be made disposable. By making the cover plate disposable, cleaning of the cover plate can be made unnecessary.

In order to suitably prevent the resin from overrunning from the periphery of the object to be molded and sticking to the molding surface of the first molding die, the outer shape of the cover plate in a plan view is preferably larger than the outer shape of the object to be molded in a plan view. In other words, it is preferable for the cover plate to extend outside of the entire periphery of the object to be molded, when the cover plate and the object to be molded are held inside the first molding die.

As a specific configuration of the first molding die, it is possible for the first molding die to hold the object to be molded by suctioning. At this time, in order for the first molding die to hold the object to be molded by suctioning, with the cover plate disposed between the first molding die and the object to be molded, it is preferable for the cover plate to have a plurality of through holes corresponding to a plurality of suction ports provided to the first molding die.

In this configuration, it is preferable to hold the cover plate by suctioning, with the cover plate covering some of the plurality of suction ports provided to the first molding die.

With this configuration, the cover plate can be held by suctioning through the suction ports provided to the first molding die. In this manner, the structure for attaching the cover plate to the molding surface of the first molding die can be simplified.

Possible approaches for attaching the cover plate to the first molding die include an approach of fixing the cover plate by suctioning to hold the cover plate, as described above, and an approach of mechanically fixing the cover plate.

With the approach for fixing the cover plate by suctioning to hold the cover plate together with the object to be molded, the cover plate as well as the object to be molded are released from the first molding die when the operation of suctioning to hold the first molding die is stopped. Therefore, in order to remove the object to be molded and the cover plate from the first molding die separately, the resin molding apparatus preferably also includes a holding mechanism that is provided around the first molding die, and that temporarily fixes the cover plate mechanically to a position attached to the first molding die.

As a specific embodiment for automatically attaching the cover plate to the first molding die, the resin molding apparatus preferably includes: a cover plate storage where the cover plate before being attached to the first molding die is stored; and a cover plate conveying mechanism that conveys the cover plate between the cover plate storage and the first molding die.

The cover plate according to the present invention is used in a resin molding apparatus including a first molding die that holds an object to be molded and a second molding die that is provided in a manner facing the first molding die and has a cavity for holding resin material, the cover plate being provided between the object to be molded and the first molding die, covering a molding surface of the first molding die, and having rigidity for maintaining a shape of the cover plate.

A method for producing a resin molded product using the resin molding apparatus described above is also an aspect according to the present invention.

### One Embodiment of Present Invention

One embodiment of a resin molding apparatus according to the present invention will now be explained with reference to some drawings. Note that all of the drawings described below are schematic representations, with some omissions and exaggerations made as appropriate, to facilitate understanding. The same components are denoted by the same reference numerals, and the explanations thereof will be omitted as appropriate.

### Overall Configuration of Resin Molding Apparatus 100

A resin molding apparatus 100 according to the present embodiment is intended to manufacture a resin molded product P by molding an electronic components Wx mounted on a substrate W, as an object to be molded, with resin material J. Examples of the substrate include a metal substrate, a resin substrate, a glass substrate, a ceramic substrate, a circuit board, a semiconductor substrate, a lead frame, a silicon wafer, and a glass wafer. An example of the resin material J is granular resin.

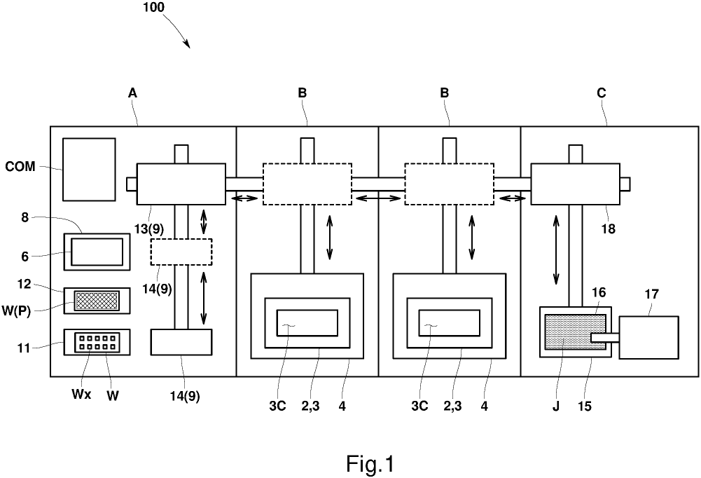

As illustrated in FIG. 1, the resin molding apparatus 100 includes a substrate supplying/storage module A, two resin-molding modules B, and a resin material supplying module C, as components thereof. These components (the modules A to C) can be attached to and detached from the respective components and exchangeable.

The substrate supplying/storage module A includes a substrate receiving unit 11 that receives a pre-molding substrate W from outside, a substrate storage unit 12 that stores therein a molded substrate W (resin molded product P), a conveying mechanism 13 that conveys the pre-molding substrate W and the resin molded product P, and a transfer mechanism 14, such as a transfer robot, that transfers the pre-molding substrate W and the resin molded product P to and from the conveying mechanism 13.

The conveying mechanism 13 conveys a pre-molding substrate W from the substrate supplying/storage module A to the resin-molding module B, and conveys a resin molded product P from the resin-molding module B to the substrate supplying/storage module A. The transfer mechanism 14 also transfers a pre-molding substrate W from the substrate receiving unit 11 to the conveying mechanism 13, and transfers a resin molded product P from the conveying mechanism 13 to the substrate storage unit 12.

Each of the resin-molding modules B includes an upper molding die 2 which is a first molding die holding the substrate W, a lower molding die 3 that is a second molding die provided with the cavity 3C, and a molding die clamping mechanism 4 for clamping the upper molding die 2 with the lower molding die 3. A specific configuration will be described later.

The resin material supplying module C includes a moving table 15, a resin material container 16 that is placed on the moving table 15, a resin material feeding mechanism 17 that measures an amount of and feeds the resin material J into the resin material container 16, and a resin material supplying mechanism 18 that conveys the resin material container 16 and supplies the resin material J into the cavity 3C of the lower molding die 3.

In the resin material supplying module C, the moving table 15 is moved between a position where the resin material feeding mechanism 17 feeds the resin, and a transfer position where the resin material container 16 is transferred to the resin material supplying mechanism 18. The resin material supplying mechanism 18 conveys the resin material container 16 holding the resin material J from the resin material supplying module C to the resin-molding module B, and conveys the resin material container 16 after supplying the resin material J from the resin-molding module B to the resin material supplying module C.

### Specific Configuration of Resin-Molding Module B

A specific configuration of the resin-molding module B according to the present embodiment will now be explained.

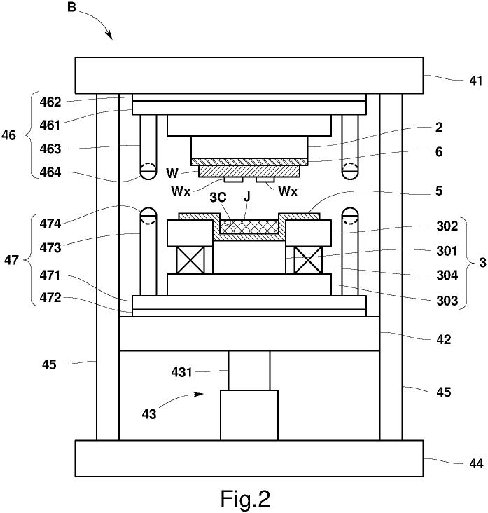

As described above, the resin-molding module B includes the upper molding die 2 that holds the substrate W, the lower molding die 3 that is provided with the cavity 3C, and the molding die clamping mechanism 4 to which the upper molding die 2 and the lower molding die 3 are attached and that clamps the upper molding die 2 and the lower molding die 3, as illustrated in FIG. 2.

The molding die clamping mechanism 4 includes an upper fixed platen 41 on which the upper molding die 2 is mounted, a movable platen 42 on which the lower molding die 3 is mounted, and a driving mechanism 43 for moving the movable platen 42 in vertical directions.

The upper fixed platen 41 has a bottom surface on which the upper molding die 2 is mounted, and is fixed on the top ends of a plurality of support columns 45, in a manner facing the movable platen 42.

The movable platen 42 has a top surface on which the lower molding die 3 is mounted, and is supported by the support columns 45 provided upright from the lower fixed platen 44, in a vertically movable manner.

The driving mechanism 43 is provided between the movable platen 42 and the lower fixed platen 44, and moves the movable platen 42 in vertical directions so that the upper molding die 2 and the lower molding die 3 are clamped thereby. The driving mechanism 43 according to the present embodiment is a linear motion driving mechanism that moves the movable platen 42 in vertical directions using a ball screw mechanism 431 that converts rotation of a servomotor or the like into a linear movement, but may also be a linkage driving mechanism that transmits a power source such as a servomotor to the movable platen 42 using a linkage mechanism such as a toggle linkage.

An upper molding die holding portion 46 is provided between the upper molding die 2 and the upper fixed platen 41. The upper molding die holding portion 46 includes a heater plate 461 for heating the upper molding die 2, a heat insulating member 462 provided on a top surface of the heater plate 461, a side wall member 463 provided on the bottom surface of the heater plate 461 in a manner surrounding the upper molding die 2, and a seal member 464 provided on the bottom end of the side wall member 463.

Between the lower molding die 3 and the movable platen 42, by contrast, a lower molding die holding portion 47 is provided. The lower molding die holding portion 47 includes a heater plate 471 that heats the lower molding die 3, a heat insulating member 472 provided on a bottom surface of the heater plate 471, a side wall member 473 provided on a top surface of the heater plate 471 in a manner surrounding the lower molding die 3, and a seal member 474 provided on a top end of the side wall member 473. When the molding dies are clamped by the driving mechanism 43, the seal member 464 on the side wall member 463 and the seal member 474 on the side wall member 473 are brought into close contact with each other, and the space where the upper molding die 2 and the lower molding die 3 are housed is sealed from the outer air. Note that one of the seal member 464 and the seal member 474 may be omitted.

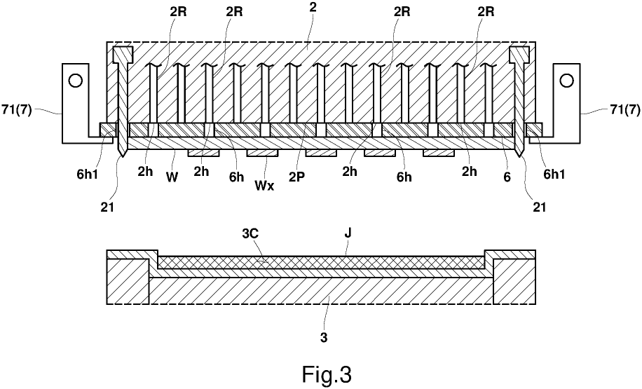

The upper molding die 2 holds the substrate W by suctioning the back surface of the substrate W. As illustrated in FIG. 3, suction ports 2h are formed on the bottom surface of the upper molding die 2, and suction channels 2R connected to the respective suction ports 2h are formed inside the upper molding die 2. The suction channels 2R are connected to an external suction device (not illustrated).

As illustrated in FIG. 2, the lower molding die 3 is provided with a cavity 3C where the electronic components Wx mounted on the substrate W and the resin material J are received. Specifically, the lower molding die 3 includes a bottom member 301 that is a single member forming the bottom surface of the cavity 3C, and a side surface member 302 surrounding the bottom member 301. The cavity 3C is formed by the top surface of the bottom member 301 and the inner peripheral surfaces of the side surface member 302.

The side surface member 302 is provided vertically movably with respect to the bottom member 301. Specifically, the base plate 303 of the lower molding die 3 is supported by a plurality of elastic members 304, such as coil springs (see FIG. 2). The lower molding die 3 according to the present embodiment is covered with a release film 5, in order to improve the releasability of the resin molded product P. An air vent (not illustrated) for discharging the air and gas may be provided on the top surface of the side surface member 302 (the abutting surface between the side surface member 302 and the substrate W).

### Cover Plate 6

As particularly illustrated in FIG. 3, the resin-molding module B according to the present embodiment includes a cover plate 6 to be provided between the substrate W and the upper molding die 2, and covering the molding surface 2P of the upper molding die 2.

The cover plate 6 has rigidity for maintaining its own shape, and is made of a member having rigidity for maintaining its own shape (e.g., a flat plate shape) in an natural condition where there is no application of any external force other than the gravity. The cover plate 6 is made of metal, resin, or paper, for example.

The thickness of the cover plate 6 depends on its material, but is usually preferably about 0.2 mm to about 0.5 mm. When the thickness is less than about 0.2 mm, it may be difficult to maintain its own shape in the natural condition. By contrast, when the thickness is greater than about 0.5 mm, the cover plate 6 may experience a difficulty in maintaining its own shape in the natural condition, because, depending on its size, the cover plate 6 may fail to support its own weight, and may also cause an increase in cost and deterioration of the ease of handling due to its own weight. In particular, when paper is used and the thickness is greater than about 0.5 mm, the amount of deformation caused by the molding pressure increases, and it becomes difficult to ensure the flatness of a resin molded portion of the resin molded product.

“Having rigidity for maintaining its own shape” herein means that, when the cover plate 6 is held like a cantilever, with one end supported and established as a fixed end, the strength thereof is set to such a level that the cover plate 6 does not get deformed by its own weight, or the amount of deformation caused by its own weight is at an ignorable level in the practical use. Alternatively, “having rigidity for maintaining its own shape” means that the strength is set to such a level that the cover plate 6 can be maintained upright when the cover plate 6 is placed vertically, with the bottom end thereof supported. Note that the meaning of “having rigidity for maintaining its own shape” is intended to exclude any object such as a release film that becomes easily deformed, fails to maintain its own shape, and becomes wrinkled, when the object is picked up.

An example of the cover plate 6 made of a metal material includes a flat plate made of stainless steel or copper. An example of the cover plate 6 made of a resin material includes a flat plate made of a plastic such as glass epoxy resin. An example of the cover plate 6 made of a paper material include one made of thick paper such as dust-proof paper. The cover plate 6 is preferably heat resistant, because the molding dies (the upper molding die 2, the lower molding die 3) are heated.

At this time, particularly when the cover plate 6 is made of metal or resin, the cover plate 6 can be easily cleaned after the use in resin molding, and to be reused for subsequent resin molding, so that it becomes possible to reduce the running cost, compared with when a release film is used. Furthermore, with the cover plate 6 made of resin or paper, in particular, the cover plate 6 can be manufactured at low costs, and can be made disposable. By making the cover plate 6 disposable, cleaning of the cover plate 6 can be unnecessary.

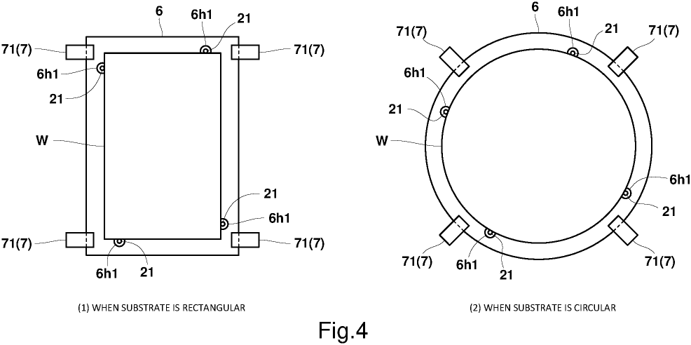

As illustrated in FIG. 4, the outer shape of the cover plate 6 in a plan view is larger than the outer shape of the substrate W in a plan view. As illustrated in FIG. 4, when the substrate W has a rectangular shape, it is possible to use a rectangular cover plate 6 having an outer shape larger than the substrate W. When the substrate W has a circular shape, it is possible to use a circular cover plate 6 having an outer shape larger than the substrate W. Because the cover plate 6 is larger than the substrate W in the manner described above, it is possible to prevent the molten resin material J from creeping onto the back surface of the substrate W, via an air vent, for example, and coming into contact with the molding surface 2P of the upper molding die 2.

As illustrated in FIG. 3, the cover plate 6 has a plurality of through holes 6h, in a manner corresponding to the suction ports 2h provided to the molding surface 2P of the upper molding die 2. Each of the through holes 6h has been formed to have a diameter larger than that of the suction port 2h, and is configured in such a manner that communication between the through hole 6h and the suction port 2h is ensured even when the cover plate 6 is slightly displaced.

Furthermore, the cover plate 6 is suctioned and held by covering some of the plurality of suction ports 2h provided to the molding surface 2P of the upper molding die 2. In other words, the suction ports 2h provided to the molding surface 2P of the upper molding die 2 include those communicating with the respective through holes 6h of the cover plate 6 to suck and hold the substrate W, and those covered by the cover plate 6 to suck and to hold the cover plate 6.

In addition, as illustrated in FIGS. 3 and 4, the cover plate 6 is provided with through holes 6h1 through which alignment pins 21 are passed, respectively, the alignment pins 21 ensuring the alignment by being brought into contact with the peripheral end surface of the substrate W disposed on the upper molding die 2. With these alignment pins 21 passed through the respective through holes 6h1, an alignment between the substrate W and the upper molding die 2 is ensured. Note that an elastic member (not illustrated) is provided on the upper side of the alignment pins 21 of the upper molding die 2, and does not interfere with the lower molding die 3 at the time of clamping.

In the present embodiment, four alignment pins 21 are provided, but an appropriate number of alignment pins 21 may be provided at appropriate positions depending on the size, the shape, the material, the molding temperature, and the like of the substrate W. Furthermore, when it is possible to form holes in the substrate W, the alignment pins 21 may be inserted into the respective holes using pilot pins, for example, to achieve the alignment, instead of bringing the alignment pins 21 into contact with the end surface of the substrate W.

As illustrated in FIGS. 3 and 4, the resin-molding module B also includes a holding mechanism 7 that temporarily fixes the cover plate 6 mechanically at the position attached to the upper molding die 2.

The holding mechanism 7 includes holding members 71 provided around the upper molding die 2 and temporarily fixing the cover plate 6 mechanically at the position attached to the upper molding die 2. The holding members 71 are provided at a plurality of positions (four positions in FIG. 4) around the upper molding die 2. The holding members 71 hold the cover plate 6 by becoming hooked onto the outer edge of the bottom surface of the cover plate 6, and prevents the cover plate 6 from falling. Because the holding members 71 hook the cover plate 6, the cover plate 6 does not fall from the upper molding die 2 even when the upper molding die 2 stops suctioning to hold the cover plate 6.

Furthermore, in the present embodiment, as illustrated in FIG. 1, the substrate supplying/storage module A described above includes a cover plate storage 8 that stores therein the cover plate 6, and a cover plate conveying mechanism 9 that conveys the cover plate 6 between the cover plate storage 8 and the upper molding die 2.

The cover plate storage 8 according to the present embodiment not only stores therein the cover plate 6 before use, before being attached to the upper molding die 2, but also stores therein a used cover plate 6 after having been attached to the upper molding die 2. Note that the cover plate 6 before use and the cover plate 6 after use may be stored in separate storages, or when the used cover plate 6 is disposable, the used cover plate 6 may be disposed in a disposal box (not illustrated).

The cover plate conveying mechanism 9 is implemented by using the conveying mechanism 13 and the transfer mechanism 14 described above. In other words, the conveying mechanism 13 conveys the cover plate 6 before use from the substrate supplying/storage module A to the resin-molding module B, and conveys the cover plate 6 after use from the resin-molding module B to the substrate supplying/storage module A. The transfer mechanism 14 transfers the cover plate 6 before use from the cover plate storage 8 to the conveying mechanism 13, and transfers the used cover plate 6 from the conveying mechanism 13 to the cover plate storage 8. Note that the cover plate conveying mechanism 9 may be provided as a mechanism dedicated to cover plates, separately from the conveying mechanism 13 and the transfer mechanism 14 described above.

### Operation of Resin Molding Apparatus 100

A resin molding (resin sealing) operation performed by the resin molding apparatus 100 will now be explained with reference to FIGS. 1 and 5 to 8. The following operation is achieved by causing a control unit COM provided in the substrate supplying/storage module A to control each unit included in the resin molding apparatus 100, for example. Note that the control unit COM is a specialized or general-purpose computer including a CPU, an internal memory, an input/output interface, an AD converter, and the like.

### Step of Supplying Cover Plate

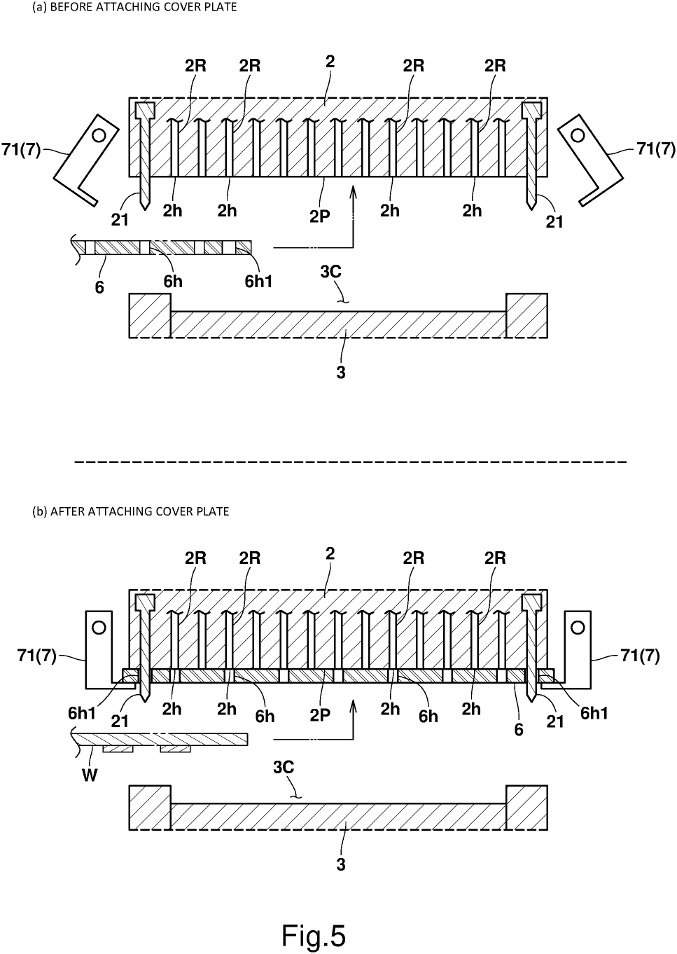

In the substrate supplying/storage module A, the transfer mechanism 14 transfers the cover plate 6 before use from the cover plate storage 8 to the conveying mechanism 13 that is positioned at a predetermined standby position (see FIG. 1). The conveying mechanism 13 is then moved into the resin-molding module B, and the opened upper molding die 2 holds the cover plate 6 by suctioning (see (a) to (b) in FIG. 5). At this time, the alignment pins 21 are inserted into the respective through holes 6h1 so as to achieve the alignment of the cover plate 6. After the upper molding die 2 holds the cover plate 6 by suctioning, the cover plate 6 is fixed by the holding members 71 of the holding mechanism 7 (see FIG. 5(b)). The conveying mechanism 13 is then returned to the predetermined standby position.

### Step of Supplying Pre-Molding Substrate

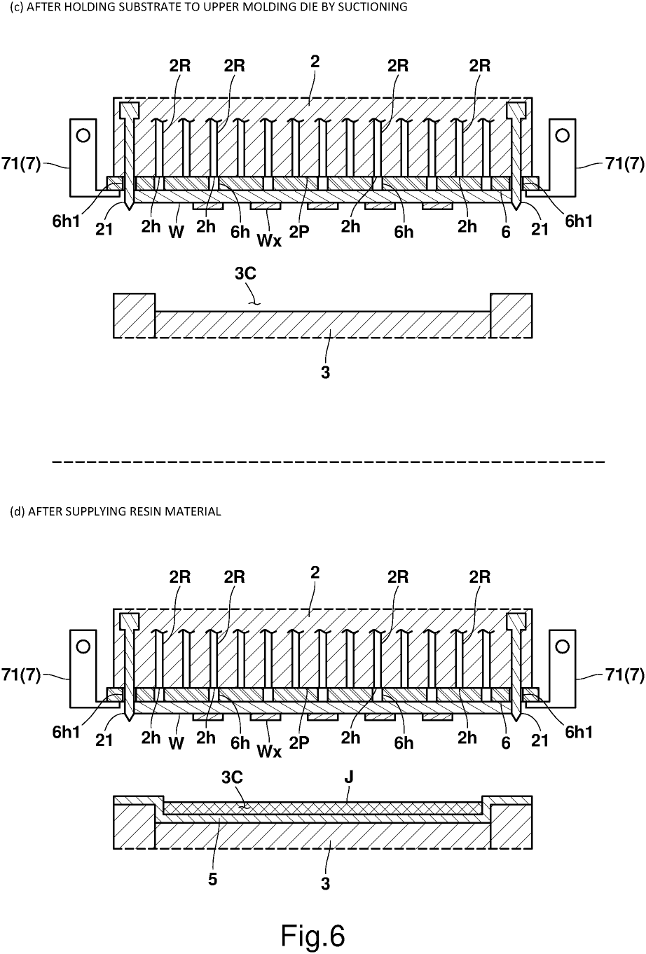

In the substrate supplying/storage module A, the transfer mechanism 14 then transfers the pre-molding substrate W from the substrate receiving unit 11 to the conveying mechanism 13 that is at a predetermined standby position (see FIG. 1). The conveying mechanism 13 is then moved into the resin-molding module B, and the open upper molding die 2 suctions and holds the pre-molding substrate W (see (c) in FIG. 6). At this time, the alignment pins 21 come into contact with the peripheral end surface of the pre-molding substrate W so as to achieve the alignment of the pre-molding substrate W, and the cover plate 6 is sandwiched between the pre-molding substrate W and the molding surface 2P of the upper molding die 2. The conveying mechanism 13 is then returned to the predetermined standby position.

### Step of Measuring Resin

Meanwhile in the resin material supplying module C, the release film 5 is formed into a predetermined shape, the moving table 15 having been at a predetermined standby position is moved, and the release film 5 and a frame member (not illustrated) are placed sequentially on the moving table 15, together forming a resin material container 16. The resin material container 16 is then moved to the resin material feeding mechanism 17 (see FIG. 1). A predetermined amount of the resin material J is then poured inside of the frame member of the resin material container 16, from the resin material feeding mechanism 17. The moving table 15 is then returned to the predetermined standby position.

### Step of Supplying Resin

The resin material supplying mechanism 18 that is at a predetermined standby position is then moved, and receives the resin material container 16 holding the resin material J from the moving table 15. The resin material supplying mechanism 18 is then moved into the resin-molding module B, and the release film 5 of the resin material container 16 and the resin material J stored in the resin material container 16 are supplied into the cavity 3C of the open lower molding die 3 (see (d) in FIG. 6). The resin material supplying mechanism 18 is then returned to the predetermined standby position. The release film 5 may be brought into close contact with the cavity 3C, before the resin material J is supplied into the cavity 3C.

### Step of Molding With Resin

After the step described above, in the resin-molding module B, the driving mechanism 43 lifts the movable platen 42 to bring the seal member 464 of the upper molding die holding portion 46 into close contact with the seal member 474 of the lower molding die holding portion 47, together forming a sealed space. In this positioning, an exhaust mechanism (not illustrated) evacuates the air from the sealed space to achieve the vacuum.

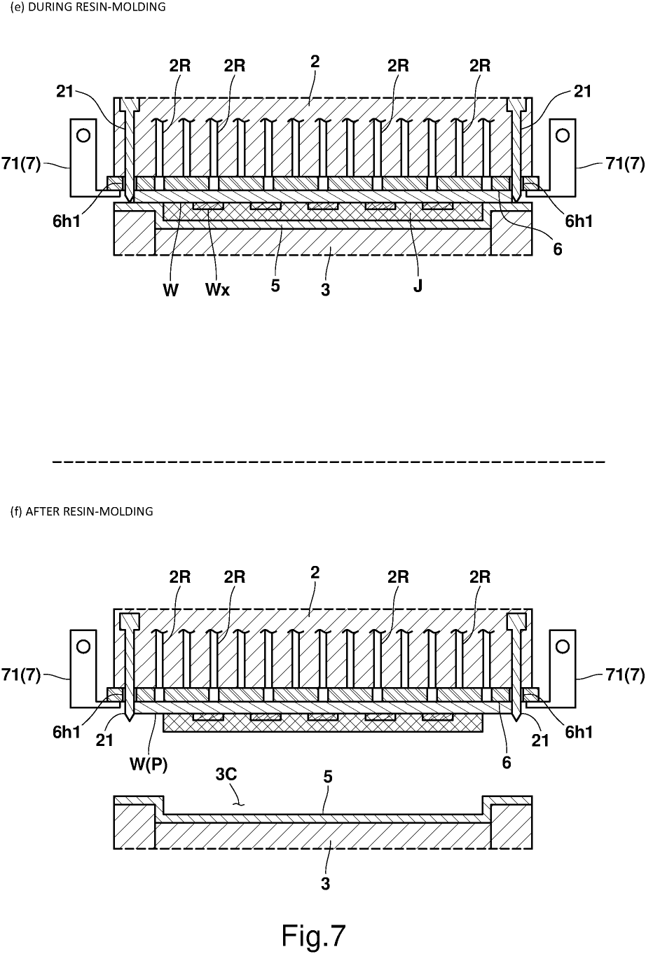

The driving mechanism 43 then lifts the movable platen 42 further, causing the upper molding die 2 to be pushed against the side surface member 302, thereby causing the elastic member 304 to become compressed and deformed, so that the electronic components Wx of the substrate W are immersed in the resin material J, and the surface of the substrate W where the components are mounted is covered by the resin material J (see (e) FIG. 7). In this condition, the upper molding die 2 and the lower molding die 3 are clamped at a predetermined clamping pressure, and are heated. After a predetermined time elapses, the molding die clamping mechanism 4 brings down the lower molding die 3, so as to open the upper molding die 2 and the lower molding die 3 (see (f) in FIG. 7). The sealed space may be brought back to the atmospheric pressure while the molding dies are being clamped together.

### Step of Taking Out Molded Substrate

The conveying mechanism 13 of the substrate supplying/storage module A is then moved to receive the resin molded product P from the opened upper molding die 2. At this time, the upper molding die 2 having been holding the cover plate 6 by suctioning releases the cover plate 6, or also reversely ejects gas from the suction ports 2h toward the back surface of the resin molded product P, so that the resin molded product P is removed from the upper molding die 2 (see FIG. (g) in 8). Because the cover plate 6 is fixed by the holding mechanism 7, the cover plate 6 remains attached to the upper molding die 2. The conveying mechanism 13 having received the resin molded product P is then moved to a predetermined transfer position by the transfer mechanism 14. The transfer mechanism 14 transfers and stores the resin molded product P from the conveying mechanism 13 to the substrate storage unit 12 (see FIG. 1).

### Step of Taking Out Cover Plate

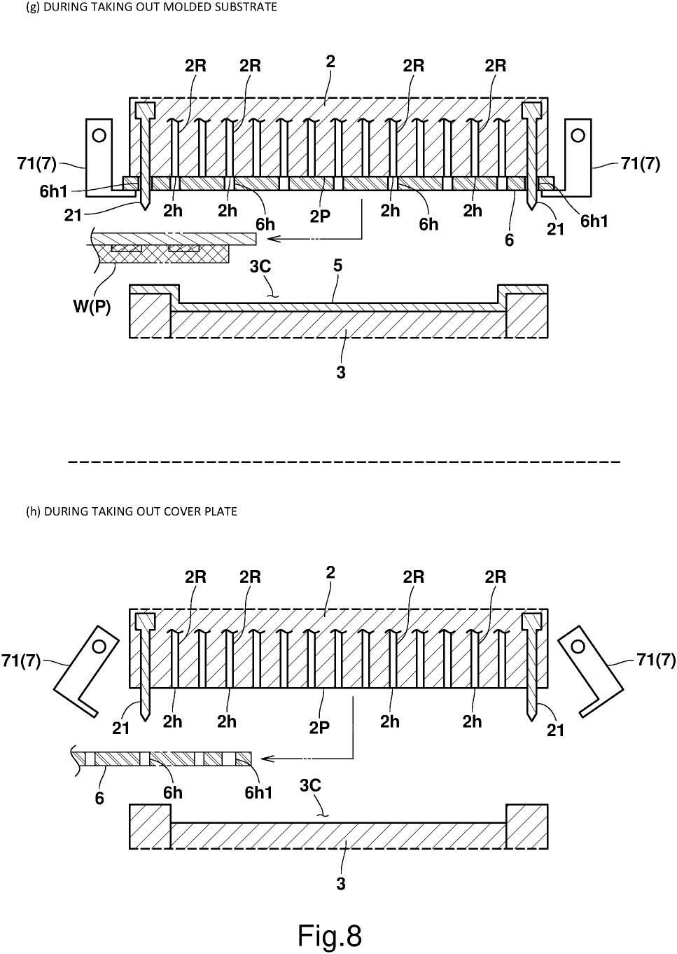

Finally, the conveying mechanism 13 included in the substrate supplying/storage module A is moved to receive the used cover plate 6 from the open upper molding die 2. At this time, the upper molding die 2 holding the cover plate 6 by suctioning releases the cover plate 6, or also reversely ejects gas from the suction ports 2h toward the cover plate 6. At the same time, the holding mechanism 7 releases the cover plate 6 having been fixed thereby, so that the used cover plate 6 is removed from the upper molding die 2 (see (h) in FIG. 8). The conveying mechanism 13 having received the used cover plate 6 is then moved to the predetermined transfer position of the transfer mechanism 14. The transfer mechanism 14 then transfers the used cover plate 6 from the conveying mechanism 13 to the cover plate storage 8, and stores therein the used cover plate 6. The release film 5 on the lower molding die 3 is also removed, separately. In this manner, resin molding is completed.

### Advantageous Effects of Present Embodiment

With the resin molding apparatus 100 according to the present embodiment, because the cover plate 6 covers the molding surface 2P of the upper molding die 2 that holds the substrate W, it is possible to prevent the resin from sticking to the molding surface 2P of the upper molding die 2, without using a release film on the upper molding die 2. Therefore, it is possible to reduce the running cost and the disposal cost accrued by using the release film on the upper molding die 2. Even if there is any substance such as resin or a foreign substance sticking on the molding surface 2P of the upper molding die 2, the sticking substance is covered by the cover plate 6, so that it is possible to prevent product defects such as cracking of the substrate W. In addition, even if there is any substance such as a foreign substance or dirt sticking on the back surface of the substrate W (the surface not to be molded with resin, that is, the surface on the side facing the molding surface 2P of the upper molding die 2), the cover plate 6 absorbs the impact applied from the upper molding die 2 to the substrate W, the impact caused by the presence of the sticking substance. Therefore, it is possible to prevent the substrate W from becoming cracked or broken. By covering the molding surface 2P of the upper molding die 2 with the cover plate 6 in the manner described above, the safety of the product can be ensured, and the resin molding apparatus 100 can be operated for a long period of time.

In addition, because the cover plate 6 has rigidity for maintaining its own shape, and is made of a member capable of maintaining its own shape in a natural condition, the cover plate conveying mechanism 9 for conveying the cover plate 6 can be simplified. For example, it is possible to convey the cover plate 6 using a conveying mechanism having the same configuration as the conveying mechanism 13 for conveying the substrate W. In the present embodiment, the shared conveying mechanism 13 conveys the substrate W and the cover plate 6.

Furthermore, because the cover plate 6 is not soft like a release film, and maintains its shape in a natural condition where there is no application of any external force other than the gravity, the cover plate 6 does not get wrinkled when attached to the molding surface 2P of the upper molding die 2, and the molding die structure does not become complicated, compared with when a release film is used.

### Other Modified Embodiments

Note that the present invention is not limited to the embodiment described above.

For example, in the embodiment described above, the upper molding die 2 is configured to hold the substrate W and the cover plate 6 by suctioning separately, but the upper molding die 2 may be configured to hold the substrate W and the cover plate 6 by suctioning simultaneously. In such a case, it is possible for the substrate W and the cover plate 6 to be stacked on top of each other before being conveyed by the conveying mechanism 13, and the conveying mechanism 13 may convey the substrate W and the cover plate 6 stacked on top of each other onto the upper molding die 2.

In the embodiment described above, the substrate W and the cover plate 6 are removed separately from the upper molding die 2, but the substrate W and the cover plate 6 may be removed simultaneously from the upper molding die 2. In this case, to take out the substrate W and the cover plate 6 using the conveying mechanism 13, the upper molding die 2 may configured to, after causing the holding mechanism 7 to release the cover plate 6 having been fixed thereby, release the substrate W and the cover plate 6 having been suctioned and held thereto, and the conveying mechanism 13 may be configured to receive and take out both of the substrate W and the cover plate 6. When a configuration in which the substrate W and the cover plate 6 are simultaneously removed from the upper molding die 2 is used, it is possible to use a configuration not using the holding mechanism 7 according to the embodiment.

In addition, the cover plate 6 according to the embodiment is configured to extend out along the entire periphery of the substrate W, but may also be configured to extend outside of the substrate W in a part where resin is likely to creep out, e.g., the part where an air vent is provided, for example.

Furthermore, in addition to the configuration covering the entire molding surface of the upper molding die 2, the cover plate 6 may be configured to cover a part of the molding surface 2P of the upper molding die 2. To use such a configuration, the cover plate 6 may cover a part where the resin is likely to creep out, that is, a predetermined range including the outer edge of the substrate W. In such a configuration, a recess recessed by the thickness of the cover plate 6 may be formed on the upper molding die 2, so that the cover plate 6 is fitted and disposed inside the recess.

In addition, in the embodiment described above, the cover plate 6 is configured to be suctioned and held using the suction ports 2h provided to the upper molding die 2. However, when the holding mechanism 7 is used, the cover plate 6 may be configured not to be suctioned nor to be held using the suction ports 2h. In such a configuration, the cover plate 6 is provided with a through hole 6h corresponding to every one of the suction ports 2h provided to the upper molding die 2.

In the embodiment described above, the cover plate 6 is replaced every time resin molding is performed. However, the cover plate 6 may be replaced for multiple times resin molding is performed. The cover plate 6 may be a single member or may be separable into a plurality of members.

In addition, the cover plate 6 may be formed by laminating a plurality of peelable films, and the outermost film of the cover plate 6 may be peeled off and used every time resin molding is performed.

In the embodiment described above, the substrate supplying/storage module A includes the cover plate storage 8 and the cover plate conveying mechanism 9. However, the substrate supplying/storage module A may be installed in another module, or a dedicated cover plate supplying/storage module may be provided separately from the modules A to C.

The resin molding apparatus according to the embodiment described above performs compression molding, but may also perform transfer molding. In such a configuration, the cover plate is disposed on the molding die that holds the object to be molded, between the molding surface of the molding die and the object to be molded.

In the resin molding apparatus according to the embodiment described above, the upper molding die is configured to hold the object to be molded, but the lower molding die may be configured to hold the object to be molded. In such a configuration, the cover plate is disposed between the lower molding die and the object to be molded.

In the embodiment described above, the two resin-molding modules B are connected between the substrate supplying/storage module A and the resin material supplying module C, but the substrate supplying/storage module A and the resin material supplying module C may be integrated into one module, and the resin-molding module B may be connected to the module. It is also possible for the resin molding apparatus not to be modularized into modules, as in the embodiment described above.

In the embodiment described above, the resin material is granular resin, but may also be liquid resin.

In addition, the present invention is not limited to the above embodiment, and it should be needless to say that various modifications can be made without departing from the gist of the present invention.

### INDUSTRIAL APPLICABILITY

According to the present invention, it is possible to prevent the resin from sticking to the molding surface of the first molding die that holds the object to be molded, without using a release film.

1. A resin molding apparatus that molds resin on an object to be molded, the resin molding apparatus comprising:
a first molding die that holds the object to be molded;
a second molding die that is provided in a manner facing the first molding die and that has a cavity for holding resin material; and
a cover plate that is provided between the object to be molded and the first molding die, that covers a molding surface of the first molding die, and that has rigidity for maintaining a shape of the cover plate.

2. The resin molding apparatus according to claim 1, wherein the cover plate is made of a member having rigidity for maintaining the shape of the cover plate against a weight of the cover plate.

3. The resin molding apparatus according to claim 1, wherein the cover plate is made of metal, resin, or paper.

4. The resin molding apparatus according to claim 1, wherein an outer shape of the cover plate in a plan view is larger than an outer shape of the object to be molded in a plan view.

5. The resin molding apparatus according to claim 1, wherein
the first molding die holds the object to be molded by suctioning, and
the cover plate has a plurality of through holes corresponding to a plurality of suction ports provided to the first molding die.

6. The resin molding apparatus according to claim 5, wherein the cover plate is held by suctioning, with the cover plate covering some of the plurality of suction ports provided to the first molding die.

7. The resin molding apparatus according to claim 1, further comprising a holding mechanism that is provided to the first molding die, and that temporarily fixes the cover plate mechanically to a position attached to the first molding die.

8. The resin molding apparatus according to claim 1, further comprising:
a cover plate storage where the cover plate before being attached to the first molding die is stored; and
a cover plate conveying mechanism that conveys the cover plate between the cover plate storage and the first molding die.

9. A cover plate that is used in a resin molding apparatus including a first molding die that holds an object to be molded and a second molding die that is provided in a manner facing the first molding die and has a cavity for holding resin material, wherein
the cover plate is provided between the object to be molded and the first molding die, covers a molding surface of the first molding die, and has rigidity for maintaining a shape of the cover plate.

10. A method for producing a resin molded product_using the resin molding apparatus according to claim 1.
